(19) United States
(12) Patent Application Publication
(10) Pub. No.: US 2006/0017602 A1
(43) Pub. Date: Jan. 26, 2006

(54) Mobile radio receiver with hybrid gain setting and method for gain setting

(75) Inventors: Giuseppe Li Puma, Bochum (DE); Duyen Pham-Stabner, Ratingen (DE); Dietolf Seippel, Bottrop (DE)

Correspondence Address: BAKER BOTTS L.L.P.;PATENT DEPARTMENT, 98 SAN JACINTO BLVD., SUITE 1500, AUSTIN, TX, 78701-4039, US

(73) Assignee: Infineon Technologies AG.

(21) Appl. No.: 11/186,482

(22) Filed: Jul. 21, 2005

(30) Foreign Application Priority Data
Jul. 22, 2004 (DE) DE 102004035609.2

(51) Int. Cl. H03M 1/34

(52) U.S. Cl. 341/164

(57) ABSTRACT

The mobile radio receiver comprises a variable amplifier (3), a first means (9, 10) for comparison of a signal, which is characteristic of the amplitude of a received signal, with at least one analogue comparison value (PDTHR), a second means (13, 14, 17) for comparison of a signal, which is characteristic of the amplitude of a received signal, with at least one digital comparison value (RSSITHR), and a third means (17, 11) for setting the gain, which is driven by the first means (9, 10) and by the second means (13, 14, 17).

### CROSS REFERENCE TO RELATED APPLICATION

This application claims priority to German Patent Application No. 10 2004 035 609.2, which was filed on Jul. 22, 2004, and is incorporated herein by reference in its entirety.

### TECHNICAL FIELD

The invention relates to a variable gain mobile radio receiver and to a corresponding method for setting the gain in a mobile radio receiver.

### BACKGROUND

Fundamentally, modern digital mobile radio receivers are designed to be able to process a wide received input signal dynamic range. In this case, it is necessary to ensure that, when the received signal power level is low, the received signal is amplified such that reliable detection of the transmitted digital information is possible.

On the other hand, when the received signal power level is high, care must generally be taken to ensure that no overdriving occurs within the receiver (this does not apply to receivers with a limiter). In mobile radio systems which use linear modulation methods such as multivalue M-PSK (PSK—phase shift keying) or M-DPSK (DPSK—differential phase shift keying), it is essential to avoid this, since, otherwise, the received signals would not be processed linearly. Signal compression or signal limiting caused by overdriving in the receiver results in the receiver performance being reduced, in particular by the bit error rate being increased, or even by signal detection becoming completely impossible. For this reason, linear signal transmission must be ensured for such linear modulation methods within the analogue part of the receiver, that is to say from the input of the LNA (Low Noise Amplifier) to the input of the analogue/digital converter.

Furthermore, when the input power is high, the received signal should not be unnecessarily amplified, since this would lead to additional receiver power consumption.

Variable gain amplifiers are thus generally provided in mobile radio receivers. In this case, the gain is generally set by means of a control system in which the signal power of a received signal which has already been amplified is first of all measured, and is then compared with a comparison value. The amplifier gain is then corrected as a function of the comparison result. Alternatively, the signal power can also be measured and compared upstream of the amplifier input.

Modern combined TDMA-FDMA mobile radio systems (time division multiple access; frequency division multiple access) such as Bluetooth operate on a burst or packet oriented basis, that is to say information is transmitted from a transmitter to a specific receiver only during a specific time slot. In this case, in a Bluetooth-specific pico network, different network subscribers can communicate with one another briefly at the same frequency but in different time slots.

In order to reduce the power consumption, the receiver is generally activated at a time only shortly before the start of the burst or packet to be received. After the activation of the receiver, the input amplifier gain must be set in accordance with the environmental parameters. At this time, that is to say before the arrival of the burst or packet to be received, it may still be possible to detect signal components from the previous time slot. If the gain setting is carried out on the basis of the signal power in the previous time slot, a gain setting such as this is generally unsuitable for the subsequent time slot. It is thus absolutely essential for the gain setting to be carried out on the basis of the signal burst to be received. In this case, only a short time period at the start of the packet, before the transmission of the actual packet data, is available for detection of the signal power and for the gain setting based on it. In the Bluetooth Standard, the signal power must be detected and the gain must be set during the transmission of the access code, which has a length of 68 to 72 bits, and the setting process should preferably be carried out even during the preamble, which has a length of 4 bits (corresponding to 4 μs), of the access code (in this context, see the Bluetooth Specification Version 1.1, Part B, Section 4.2).

As is evident from the above statements, the detection of the signal power and the subsequent gain setting are subject to stringent requirements, with regard to their speed.

A gain control system which satisfies this requirement for the analogue front end (AFE) which includes the input amplifier can be implemented by means of purely analogue circuit technology. In this case, a detector is provided at the output of the channel filter, which is connected downstream from the amplifier to be set, and indicates the peak value or root mean value of the power of the received signal in the form of its output voltage. The output voltage is compared with a threshold value voltage. The AFE can advantageously be operated in two gain modes, with low and high gain. If the threshold voltage, which is dependent on the gain mode, is undershot or exceeded, the respective other gain mode is selected. The threshold value voltage therefore takes account of whether the AFE is currently in the operating mode with low gain, or in the operating mode with high gain. The threshold value voltage in the operating mode with low gain corresponds to the ratio of the threshold value voltage in the operating mode with high gain and to the gain difference between high gain and low gain. In addition, an offset is provided between the two values for the threshold voltage in order to provide hysteresis for the switching response. One weakness of an implementation such as this is the provision of an analogue reference voltage which is as accurate as possible and from which the threshold value voltages are derived. Offset currents and offset voltages which result from component scatters and temperature changes limit the accuracy of the reference voltage, and of the threshold value voltages which are derived from it.

The document GB 2 363 921 A discloses gain setting in an AFE in a mobile radio receiver based on an analogue control loop. A received radio-frequency signal is amplified in an amplifier with selectively low or high gain, and is then down-mixed. The negative half-cycle of the mixed signal are removed by means of a diode detector. The resultant signal is filtered by means of a low-pass filter, and is then compared with a reference signal, by means of a comparator. The gain is adapted as a function of the comparison result. Switching from one gain mode to the respective other gain mode, and vice versa, takes place with hysteresis. This circuit, which is known from the prior art, has the disadvantage that a reference signal must be provided with high accuracy, whose accuracy governs the quality of the gain control.

### SUMMARY

One object of the invention is to provide a variable gain mobile radio receiver in which the gain setting is less sensitive to accuracy fluctuations in an analogue comparison voltage. The gain setting in a mobile radio receiver such as this should advantageously operate sufficiently quickly for use in a burst or packet oriented mobile radio system. A further object of the invention is to specify a corresponding method.

The object on which the invention is based can be achieved by a mobile radio receiver, comprising an amplifier with variable gain, a first comparator for comparison of a first signal, which is characteristic of the amplitude of a received signal, with at least one analogue first comparison value, a second comparator for comparison of a second signal, which is characteristic of the amplitude of a received signal, with at least one digital second comparison value and a control unit for setting the gain of the amplifier, which is driven by the first comparator and by the second comparator.

The object can also be achieved by a method for setting the gain of a variable gain amplifier in a mobile radio receiver, comprising the step of setting the gain selectively or cumulatively as a function of a first comparison of a first signal, which is characteristic of the amplitude of a received signal, with at least one analogue first comparison value, or a function of a second comparison of a second signal, which is characteristic of the amplitude of a received signal, with at least one digital second comparison value.

The mobile radio receiver according to the invention has a variable gain amplifier. A first means is also provided, for comparison of a first signal, which is characteristic of the amplitude or power of a received signal, with at least one analogue first comparison value. The mobile radio receiver according to the invention furthermore has a second means for comparison of a second signal, which is characteristic of the amplitude or power of a received signal, with at least one digital second comparison value. Finally, the mobile radio receiver according to the invention and provides a third means for setting the gain of the amplifier, which is driven by the first means and by the second means.

The mobile radio receiver according to the invention differs from mobile radio receivers which are known from the prior art in that the gain setting also makes use of a second means for comparison with a second digital comparison value in addition to a first means for comparison with a first analogue comparison value. This is thus a hybrid approach which provides not only a comparison with an analogue comparison value but also a comparison with a digital comparison value. The comparison with the digital second comparison value is less susceptible to analogue interference influences, in principle, owing to the nature of the digital signals, in particular to offset currents and offset voltages. The gain setting by the third means, which can call up not only the comparison result relating to the analogue first comparison value but also the comparison result relating to the analogue second comparison value, is thus—considered overall—less sensitive to tolerances in the analogue comparison value.

Since the comparison with an analogue comparison variable in the first means for gain setting is provided in addition to the comparison with a digital comparison variable in the second means as well, the mobile radio receiver according to the invention in principle satisfies the precondition for sufficiently fast gain setting—irrespective of the implementation of the “digital” comparison by the second means. If this speed requirement is not essential or else can be satisfied by a correspondingly quickly operating comparison with the digital variable, it would also be possible to dispense with the comparison with the analogue comparison variable.

For the purposes of the invention, it is feasible for the third means for gain setting to jointly check the comparison results of the first and second means. Alternatively, it is possible to provide for the third means to selectively to check in each case only one of the two means for comparison purposes, depending on the situation or state.

Furthermore, it should be mentioned that the expression amplifier, for the purposes of the invention, does not just mean an amplifier in the actual sense, that is to say restricted to the function of amplification, but also a signal processing chain which operates in an analogue form and comprises two or more analogue circuit components, such as the chain comprising an LNA (Low Noise Amplifier), a mixer, a channel filter and a second amplifier (post-amplifier).

The following statements relating to a signal voltage can be transferred analogously to a corresponding signal power, and vice versa.

The first means and the second means are preferably arranged in the signal path on the output side of the amplifier, in particular on the output side of a channel filter which is connected downstream from the amplifier. In this case, the first and the second signal are each characteristic of the signal amplitude or the signal power at the amplifier output. In this case, the gain setting in the mobile radio receiver according to the invention is thus based on a control system, with the amplifier being part of the closed control loop.

In the case of selective gain setting based on the comparison result of the first means or on the comparison result of the second means, it is advantageous in the case of first values of the signal amplitude or signal power of the amplifier output signal to carry out the gain setting as a function of the output signal from the second means. Conversely, in the case of second values of the signal amplitude or of the signal power of the amplifier output signal which are greater than the first values, the gain setting is carried out as a function of the output signal from the first means.

A refinement of the gain control process such as this is based on the discovery that the comparison with the digital second comparison value can be carried out with greater accuracy than the comparison with the analogue first comparison value, since digital signals are less susceptible to interference. To this extent, on the basis of the assumption of the comparison in the second means being more accurate in absolute terms irrespective of the signal amplitude or signal power than the comparison in the first means, it is expedient to carry out the gain setting for a signal at the amplifier output with low amplitude or power as a function of the comparison result with the digital second comparison value. Conversely, in the case of a signal at the amplifier output with high amplitude or power and with unchanged absolute accuracy, the reduced absolute accuracy of the comparison in the first means is less critical. If the gain setting is carried out as a function of the comparison with the analogue first comparison value for signals with a low amplitude, this offers the advantage that the setting process can be carried out very quickly.

According to one advantageous embodiment, the amplifier can be operated with a first magnitude V1 of the gain at least in a first gain mode, and can be operated with a second magnitude V2 of the gain in a second gain mode, where V1<V2. In this case, it is advantageous for the means for setting the gain of the amplifier to be designed such that. switching takes place from the first gain mode to the second gain mode exclusively as a function of the comparison in the second means. Conversely, switching takes place from the second gain mode to the first gain mode exclusively as a function of the comparison in the first means. In this case, it is advantageous for the third means for setting the gain to be designed such that switching takes place from the first gain mode to the second gain mode when the second means indicates that the second signal, which is characteristic of the signal amplitude or the signal power at the amplifier output, has fallen below the digital second comparison value. Conversely, switching should take place from the second gain mode to the first gain mode when the first means indicates that the first signal, which is characteristic of the signal amplitude at the amplifier output, has exceeded the analogue first comparison value.

If discrete gain modes, in particular two and only two gain modes, are provided instead of continuous gain adjustment, this offers the advantage that the gain setting can be carried out easily with the aid of digital circuit means. The association as described above between the two switching processes and the first and second means which initiate the switching processes is based—in a similar way to that described above—on the magnitude of the two comparison values and the signal power at the output of the amplifier which is related to this and in each case occurs at the switching time.

The amplitude threshold value (for example 100 mV) related to the amplifier output which, if undershot, means that switching must be initiated from the first gain mode with low gain to the second gain mode with high gain, is considerably less than that amplitude threshold value (for example 1000 mV) related to the amplifier output, which, if exceeded, results in switching from the second gain mode with high gain to the first gain mode with low gain. In the same way, the measured signal amplitude or signal power before switching from the first gain mode to the second gain mode is also considerably less than before switching from the second gain mode to the first gain mode. An inadvertent absolute offset voltage of, for example, 50 mV thus has a greater influence on switching from the first gain mode to the second gain mode than vice versa. It is thus expedient to control the transition from the first gain mode to the second gain mode as a function of the output signal from the second means, which tends to be more precise. The determination of the switching point from the second gain mode to the first gain mode is considerably more robust with regard to offset variables, for which reason this transition is expediently initiated as a function of the output signal from the analogue first means, which thus operates quickly.

It is advantageous for the analogue first comparison value and the digital second comparison value to be chosen such that switching takes place from the first gain mode to the second gain mode, and switching takes place from the second gain mode to the first gain mode with hysteresis with respect to the signal amplitude or signal power at the input of the amplifier. Hysteresis is provided if the following equation is satisfied:

$${V}_{LG , HG} = \frac{{V}_{HG , LG}}{{g}_{HG} / {g}_{LG}} - {V}_{OS} . \qquad ( 1 )$$

In this case, V_{LG,HG} describes the voltage threshold value, related to the amplifier output, for switching from the first gain mode to the second gain mode, V_{HG,LG} describes the voltage threshold value, related to the amplifier output, for switching from the second gain mode to the first gain mode, and V_{OS} describes an intended offset voltage other than zero. The variables g_{HG} and g_{LG} in this case indicate the gain of the second and first gain mode, respectively. An analogous equation can be derived for power-related threshold values. Furthermore, the equation 1 can be modified such that one threshold value is a power-related value, and one threshold value is a voltage-related threshold value.

When choosing an offset voltage V_{OS} other than zero, and the hysteresis associated with this, repeated, uncontrolled switching in the vicinity of the switching threshold is suppressed.

According to one advantageous embodiment, an analogue-digital converter is arranged in the signal path on the output side of the amplifier. The analogue-digital converter is used directly or indirectly for the comparison with the digital second variable in the second means. Furthermore, the analogue/digital converter is used at least for one further function within the mobile radio receiver, for example for the demodulation or determination of the RSSI information (Radio Signal Strength Indicator).

For the comparison of the second signal, which is characteristic of the signal amplitude or signal power at the amplifier output, with the digital second comparison value, either the analogue signal on the amplifier output side must be converted from analogue to digital form or, alternatively, the digital second comparison value must be converted from digital to analogue form. If the receiver has a high-resolution analogue/digital converter in any case, for example upstream of the digital demodulation, this can also be used to control the gain, in particular by the amplifier output signal being converted from analogue to digital form, after optional preprocessing (that is to say squaring and logarithm formation) for the comparison in the second means. Furthermore, as will be explained later, an existing digital/analogue converter can in some circumstances be used as part of an analogue/digital converter for gain control. The use of an analogue/digital converter which is provided in the system in any case would be indirect, when the second means accesses only variables which are provided by the system in any case, such as the RSSI information (Radio Signal Strength Indicator) in a Bluetooth system, which have been generated by means of this analogue/digital converter. The options for use of the analogue/digital converter as described above have the common feature that a high-resolution analogue/digital converter which is provided in any case is also used for accurate gain control.

The mobile radio receiver advantageously has a means for provision of digital RSSI information, in particular logarithmic RSSI information, which is characteristic of the received power, with this means comprising the analogue/digital converter mentioned above. If the mobile radio system provides such RSSI information in any case, this information can be usefully employed for gain control. In this case, the second means is designed such that it compares the RSSI information, a variable which is dependent on it or an intermediate variable in the formation of the RSSI information with the digital second comparison value. The gain can be set as a function of the comparison result.

If the analogue/digital converter which is provided in the receiver in any case operates on the basis of an iterative method, that is to say if it is not a flash analogue/digital converter but the digital value is calculated in a number of steps, this may in some circumstances also be used for digital/analogue conversion of the second digital comparison value and for comparison with the resultant digital/analogue-converted comparison value. This is the case when a comparator, which is also referred to as a one-bit quantizer, and a digital/analogue converter which drives the reference input of the comparator are provided in the analogue/digital converter. Particularly if the analogue/digital converter is implemented on the basis of the successive approximation method, this is generally the case (in this context, see J. W. Klein et al., “Elektronische Meβtechnik” [Electronic measurement technology], Teubner Verlag 1992, Section 4.2.3, analogue/digital converter with successive approximation, in particular FIG. 4.11).

Furthermore, it is necessary for the analogue/digital converter to be designed such that the digital/analogue converter can be supplied, as part of the analogue/digital converter, not only with a digital comparison variable for analogue/digital conversion of the input signal in the analogue/digital converter but also with the digital second comparison value. In this case, the digital second comparison value can be converted with high accuracy by the digital/analogue converter to an analogue reference signal. The comparator then carries out the comparison of the resultant reference signal with the signal which is characteristic of the signal amplitude or signal power. The second means is in this case preferably designed such that the comparison is carried out by reading the digital second comparison value to the digital/analogue converter, and by reading the output signal from the comparator.

The method according to the invention for setting the gain of a variable gain amplifier is characterized in that the gain is set selectively or cumulatively as a function of a first comparison or of a second comparison. In the first comparison, a first signal, which is characteristic of the amplitude or the power of a received signal, is compared with at least one analogue first comparison value, while in the case of the second comparison, a second signal, which is characteristic of the amplitude or the power of a received signal, is compared with at least one digital second comparison value.

It should be noted that the gain setting is not necessarily based on the two comparison processes being carried out at the same time, the method requires only the two comparison processes described above to be carried out in their entirety.

### BRIEF DESCRIPTION OF THE DRAWINGS

The invention will be explained in more detail in the following text using two exemplary embodiments and with reference to the drawings, in which:

FIG. 1 shows a block diagram of a first exemplary embodiment of a mobile radio receiver according to the invention;

FIG. 2 shows an illustration of the switching response for gain setting; and

FIG. 3 shows a block diagram of a second exemplary embodiment of a mobile radio receiver according to the invention.

### DETAILED DESCRIPTION

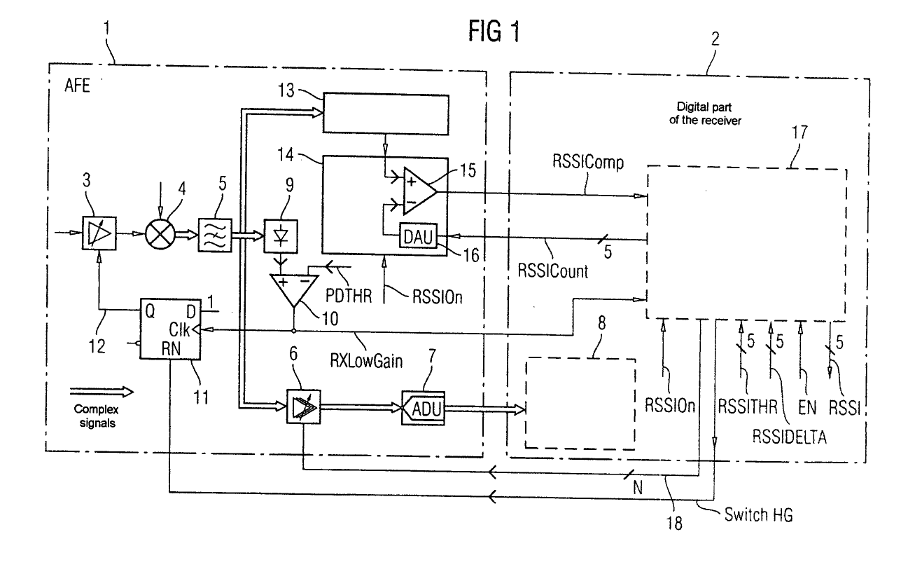

FIG. 1 shows a block diagram of a first exemplary embodiment of a mobile radio receiver according to the invention (by way of example for a Bluetooth system). The mobile radio receiver is subdivided into an analogue part (AFE) 1 and a digital part 2. A radio-frequency signal which is received from an antenna (not illustrated) is fed to a radio-frequency LNA 3, which can be operated in a gain mode with low gain and in a gain mode with high gain. The respective gain mode is selected via the control signal 12. The output signal from the LNA 3 is received by a mixer stage 4, which down-mixes the output signal from the LNA 3 to an intermediate frequency when using a heterodyne receiver concept. The implementation of the mixer stage 4 in the form of two individual mixers, which are driven by two orthogonal frequency signals (not illustrated), results in a complex signal being produced at the output of the mixer stage 4. Alternatively, it is feasible for the mixer stage 4 to down-mix the output signal from the LNA 3 directly to baseband (homodyne receiver concept). The complex output signal from the mixer stage 4 is fed to a channel filter 5, which is in the form of a polyphase filter.

The output signal from the channel filter 5 is fed into three parallel paths: into a first path for demodulation of the received signal (the lower path in FIG. 1), into a second path for analogue power measurement (the central path in FIG. 1) and a third path for obtaining the digital RSSI information (the upper path in FIG. 1).

The first path for demodulation of the received signal has a further amplifier 6 which has 2^{N} gain modes, corresponding to the total number of N binary control inputs. The complex output signal from the amplifier 6 is fed to an analogue/digital converter 7. The digitized output signal from the analogue/digital converter 7 is then processed further in a demodulator 8 in order to recover the transmitted information.

The second path has a detector 9 which determines the root mean square or peak power of the output signal from the channel filter 5, and indicates it in the form of its output voltage. Alternatively, a voltage detector can also be provided. A power detector 9 such as this is generally based on a diode detector. The output voltage from the detector 9 is received by a comparator 10 which compares the output voltage from the detector 9 with an analogue threshold value voltage PDTHR. The output signal RXLowGain of the comparator 10 is fed to the clock input Clk of a D flipflop 11. The D flipflop 11 is used to generate the control signal 12 for the LNA 3. At the start of the gain adjustment process, in particular at a time at the start of the databurst to be received, the LNA is in the gain mode with high gain, with the control signal 12 for the LNA assuming the logic 0 value. If the output signal from the detector 9 exceeds the threshold value voltage PDTHR, the output of the comparator 10 changes from the logic 0 state to the logic 1 state. At the same time, the logic 1 value at the data input D of the D flipflop is passed on to the output Q of the D flipflop as the control signal 12 when the flank change occurs at the clock input Clk. In consequence, the LNA 3 switches from the gain mode with high gain to the gain mode with low gain. Switching from the gain mode with low gain to the gain mode with high gain cannot be initiated by the analogue second path. This switching process is carried out via the third path, which will be described in the following text.

The third parallel path for obtaining the digital RSSI information has an analogue RSSI preprocessing stage 13, which receives the output signal from the channel filter 5. In this case, the analogue RSSI preprocessing stage 13 carries out a squaring process and a logarithm formation process in order to produce a logarithmic power variable. The resultant signal is received by an RSSI circuit block 14, which essentially comprises a comparator 15 and a digital/analogue converter 16 which drives the reference input of the comparator 15. The comparator 15 and the digital/analogue converter 16 are components of an analogue/digital converter which operates using the method of successive approximation, is subdivided into the RSSI circuit block 14 and a digitally operating RSSI circuit block 17, and is used to convert the output signal from the analogue RSSI preprocessing stage 13. In order to keep the input voltage at the positive input of the comparator constant during the conversion process, a sample and hold circuit (not illustrated) can be provided in the RSSI circuit block 14.

The method of successive approximation is described in chapter 4.2.3, pages 138 to 140 of the textbook “Elektronische Meβtechnik” [Electronic measurement technology] by J. W. Klein et al., Teubner Verlag, 1992. The cited text reference is in this case included by reference in the disclosure content of the application. A digital 5-bit-value data word RSSICount, which is generated in the digital RSSI circuit block 17, is fed into the digital/analogue converter 16 for analogue/digital conversion of the output signal from the analogue RSSI preprocessing stage 13. The digital RSSI circuit block 17 is used for sequence control and has a so-called finite state machine (FSM). The analogue output signal from the digital/analogue converter 16 is compared in the comparator 15 with the output signal from the analogue RSSI preprocessing stage 13.

The sequence of the method of successive approximation is described as follows: the most significant bit (MSB) of the digital signal RSSICount is set to the logic 1 value in the first approximation step, while all the other bits assume the logic 0 value. The resultant analogue signal from the digital signal RSSICount is compared in the comparator 15 with the output signal from the RSSI preprocessing stage 13. Once the output of the comparator 15 has stabilized, the output signal RSSIComp from the comparator 15 is read from the digital RSSI circuit block 17. The logic result of the comparison determines whether the logic 1 value is retained for the MSB of the signal RSSICount for the subsequent approximation steps. On the basis of the logic of the signals, the logic result of the comparison process can be used directly for the subsequent approximation steps as the most significant bit of the signal RSSICount. In the next approximation step, the second most significant bit of the signal RSSICount is determined first of all, in an analogous manner. The least significant bit (LSB) will also have been determined after a total of 5 approximation steps. The number of approximation steps required corresponds in the method of successive approximation to the bit resolution of the digital result signal.

The following list indicates the respective bit occupancy of the data word RSSICount as a function of the approximation step:

| | |
|---|---|
| 1st approximation step: | RSSICount = “10000” |
| 2nd approximation step: | RSSICount = “X1000” |
| 3rd approximation step: | RSSICount = “XX100” |
| 4th approximation step: | RSSICount = “XXX10” |
| 5th approximation step: | RSSICount = “XXXX1” |

In this case, the character “X” indicates that the respective bit has either the logic 1 value or the logic 0 value depending on the previous approximation result.

The output signal which is available from the analogue/digital converter after 5 approximation steps corresponds to digital logarithmic RSSI information. The Bluetooth-specific RSSI information also takes account of the so-called “Golden Receiver Power Range” (in this context, see the Bluetooth Specification Version 1.1, Part A, Section 4.7). Bluetooth-specific RSSI information such as this can be derived from the output signal from the analogue/digital converter. The RSSI information can be read as a digital output signal RSSI from the system for a large number of functions.

The RSSI information can be used inter alia for controlling the gain in the AFE 1, in particular for controlling the gain of the LNA 3. In the present exemplary embodiment, as described above, the switching of the gain of the LNA 3 from the gain mode with high gain to the gain mode with low gain is initiated via the analogue detector 9 and the comparator 10.

The switching in the opposite orientation, that is to say from the gain mode with low gain to the gain mode with high gain, is carried out inter alia by the comparison of the instantaneous RSSI information with a digital threshold value RSSITHR in the digital RSSI circuit block 17; if the measured RSSI information falls below the digital threshold value RSSITHR, the RSSI circuit block 17 switches the digital signal SwitchHG to the logic 1 value. The signal SwitchHG is fed to the reset input RN of the D flipflop 11, so that the output of the D flipflop 11 and the control signal 12 for the LNA 3 are set to the logic 0 value on switching of the signal SwitchHG, and the LNA 3 is switched from the gain mode with low gain back to the gain mode with high gain.

When the LNA 3 is in the gain mode with low gain, this is signalled to the digital RSSI circuit block 17 via the signal RXLowGain, which in this case assumes the logic 1 value. The RSSI information which is obtained from the digital RSSI circuit block 17 is corrected in the case of low gain on the basis of the ratio of the high to the low gain, which is signalled to the digital RSSI circuit block 17 via the digital signal RSSIDELTA. This necessarily relates only to the output variable RSSI that is produced by the RSSI circuit block 17. In contrast, the correction is not absolutely necessary for the actual comparison of the circuit-block-internal RSSI information with the variable RSSITHR, since the value of the variable RSSITHR can be chosen such that the lower gain is already taken into account. Furthermore, the RSSI circuit block knows which gain mode is currently selected, so that the circuit-block-internal RSSI information can be interpreted correctly. The value of the signal RSSIDELTA can be determined on a component-specific basis by means of a calibration measurement, for example during the chip test, the assembly of the receiver or else during operation of the receiver.

As stated above, a resolution of 5 bits results in an overall requirement for a total of 5 approximation steps before the RSSI information is available. On the basis of the procedure described above, no comparison with the digital threshold value RSSITHR can take place before this time. Additional comparison steps are thus carried out during the approximation process in the exemplary embodiment, and each allow fast comparison with the threshold value RSSITHR, in particular for fast control in the event of interference signals. A fast comparison step such as this can be carried out in each case after each approximation step, after any desired number of approximation steps, or else before the first approximation step. In the case of a fast comparison step, the digital RSSI circuit block 17 transmits the signal RSSITHR to the digital/analogue converter 16 via the connecting line for the signal RSSICount. The comparator 15 then carries out a comparison between the analogue output signal from the preprocessing stage 13 and the signal RSSITHR (in an analogue representation). If the output signal RSSIComp from the comparator 15 corresponds to the logic 0 value, the LNA 3 must be switched from the gain mode with low gain to the gain mode with high gain. For this reason, the signal SwitchHG is set to the logic 1 value in this case. In contrast, if the output signal RSSIComp from the comparator 15 corresponds to the logic 1 value, the digital RSSI circuit block 17 does not switch the gain, and the successive approximation is continued appropriately.

The following list shows the initial filling of the data word RSSICount taking account of two additional fast comparison steps:

| | |
|---|---|
| 1st approximation step: | RSSICount = “10000” |
| 1st fast comparison step: | RSSICount = RSSITHR |
| 2nd approximation step: | RSSICount = “X1000” |
| 3rd approximation step: | RSSICount = “XX100” |
| 4th approximation step: | RSSICount = “XXX10” |
| 2nd fast comparison step: | RSSICount = RSSITHR |
| 5th approximation step: | RSSICount = “XXXX1” |

The finite state machine in the digital RSSI circuit block 17 also takes account of the fact that the RSSI information is erroneous when a transition from the gain mode with high gain to the gain mode with low gain takes place or has just taken place. Such switching can be detected by the digital RSSI circuit block 17 via the signal RXLowGain.

In addition, FIG. 1 shows two digital signals RSSIOn which are used for activation of the circuit blocks for RSSI determination.

Furthermore, the digital RSSI circuit block 17 is used to control the gain of the amplifier 6, which has 2^{N} gain modes. The respective gain mode is selected via the selection line 18, which has N bit lines, in a similar manner to that already described above for the LNA 3 as a function of the measured RSSI information, or by means of a fast comparison using the comparator 15. For this purpose, the digital RSSI circuit block 17 can be supplied with two or more further comparison values RSSITHR′ (not illustrated).

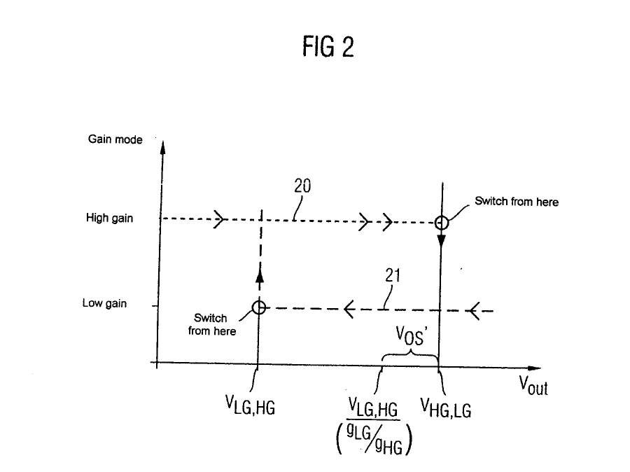

The two comparison values PDTHR and RSSITHR which determine the switching thresholds are chosen such that the switching processes behave in accordance with the characteristics illustrated in FIG. 2. In this case, the root mean square value of the voltage Vₒᵤₜ at the output of the LNA 3 is shown on the X axis, and the two gain modes of the LNA 3 are shown on the Y axis. In this case, the low switching threshold V_{LG, HG}, which is related to the output of the LNA 3, corresponds with the comparison value RSSITHR, and the high switching threshold V_{HG, LG}, which is related to the output of the LNA 3, corresponds with the comparison value PDTHR.

The characteristic 20 shows the switching from the gain mode with high gain to the gain mode with low gain, while the characteristic 21 shows the switching from the gain mode with low gain to the gain mode with high gain. The switching threshold V_{HG, LG} is in principle greater at least by the factor of the gain ratio in the different gain modes (in this context, see equation 1). Furthermore, an offset V_{OS}′ is also taken into account, which produces hysteresis between the switching points. It should be noted that, without any offset voltage V_{OS}′, there will be no hysteresis, since the output voltage will change suddenly by the gain ratio after switching to the respective other gain mode (not illustrated in FIG. 2). The profile which is illustrated for the output voltage in FIG. 2 can also be related to the output power, in a similar manner.

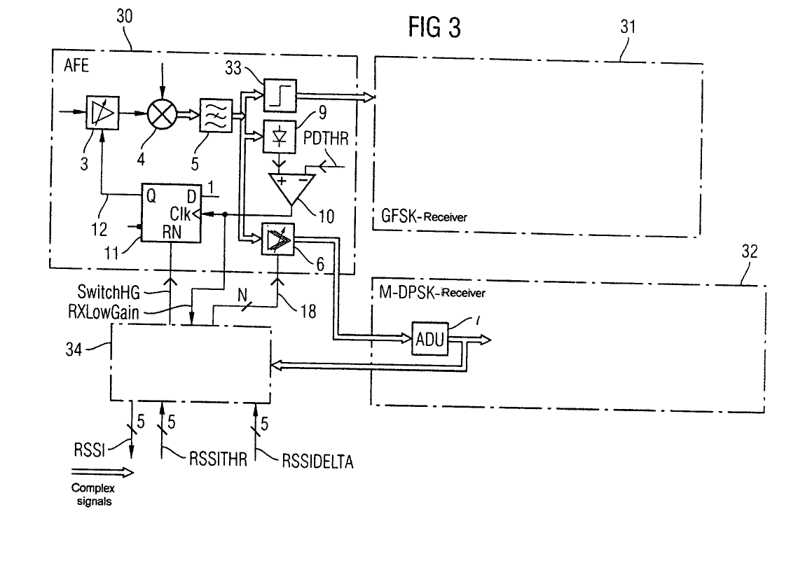

FIG. 3 shows a block diagram of a second exemplary embodiment of a mobile radio receiver according to the invention. Signals and circuit components from FIG. 1 and FIG. 3 which are provided with the same reference symbols correspond to one another. The mobile radio receiver that is illustrated in FIG. 3 is suitable not only for reception of GFSK-modulated signals (Gaussian Frequency Shift Keying) but also for reception of M-DPSK-modulated signals (Differential Phase Shift Keying with multivalue symbols M=4 or 8). In particular, the mobile radio receiver illustrated in FIG. 3 is designed for the future Bluetooth 2.0 Standard, which is based not only on GFSK but also on M-DPSK.

The mobile radio receiver has an AFE 30, a GFSK receiver section 31 and an M-DPSK receiver part 32. In order to drive the GFSK receiver section 31, the output signal from the channel filter 5 is received by a limiting amplifier (limiter) 33, and is amplified on a non-linear basis. The M-DPSK receiver 32 is driven by the linear amplifier 6. An analogue/digital converter 7 is provided on the input side of the M-DPSK receiver section 32. The transmitted information is recovered from the digitized output signal from the analogue/digital converter 7 in the downstream signal processing stages (not illustrated) of the M-DPSK receiver section 32.

Furthermore, the digital output signal from the analogue/digital converter 7 is received by a digital RSSI unit 34. The RSSI unit 34 is used to determine and produce the RSSI information. Furthermore, the RSSI unit 34 has the task of setting the gain in the amplifiers 3 and 6, with the RSSI unit 34 being used in particular to switch the gain of the LNA 3 from the gain mode with low gain to the gain mode with high gain. In this case, the RSSI unit 34 sets the gain analogously to FIG. 1 by comparison of the threshold value RSSITHR with measured RSSI information.

One significant difference between the receiver illustrated in FIG. 1 and that illustrated in FIG. 3 is that the RSSI information in FIG. 3 is obtained from the outputsignal from the analogue/digital converter 7 which drives the demodulator, while a dedicated analogue/digital converter is provided for obtaining the RSSI information in FIG. 1.

What is claimed is:

1. A mobile radio receiver, comprising:
an amplifier with variable gain,
a first comparator for comparison of a first signal, which is characteristic of the amplitude of a received signal, with at least one analogue first comparison value,
a second comparator for comparison of a second signal, which is characteristic of the amplitude of a received signal, with at least one digital second comparison value and
a control unit for setting the gain of the amplifier, which is driven by the first comparator and by the second comparator.

2. A mobile radio receiver according to claim 1,
wherein
the first comparator is arranged in the signal path on the output side of the amplifier, and the first signal is characteristic of the signal amplitude at the amplifier output, and
the second comparator is arranged in the signal path on the output side of the amplifier, and the second signal is characteristic of the signal amplitude at the amplifier output.

3. A mobile radio receiver according to claim 2,
wherein
for first values of the signal amplitude of the amplifier output signal, the gain is set as a function of the output signal from the second comparator and
for second values of the signal amplitude of the amplifier output signal which are greater than the first values, the gain is set as a function of the output signal from the first comparator.

4. A mobile radio receiver according to claim 2,
wherein
the amplifier can be operated, at least in a first gain mode, with a first magnitude V1 of the gain, and can be operated in a second gain mode with a second magnitude V2 of the gain, where V1<V2, and
the means for setting the gain of the amplifier is designed such that
switching takes place from the first gain mode to the second gain mode as a function of the comparison in the second comparator, and
switching takes place from the second gain mode to the first gain mode as a function of the comparison in the first comparator.

5. A mobile radio receiver according to claim 4,
wherein
the control unit for setting the gain is designed such that
switching takes place from the first gain mode to the second gain mode when the second comparator indicates that the second signal, which is characteristic of the signal amplitude at the amplifier output, has fallen below the digital second comparison value, and
switching takes place from the second gain mode to the first gain mode when the first comparator indicates that the first signal, which is characteristic of the signal amplitude at the amplifier output, has exceeded the analogue first comparison value.

6. A mobile radio receiver according to claim 4,
wherein
the analogue first comparison value and the digital second comparison value are chosen such that switching takes place from the first gain mode to the second gain mode, and switching takes place from the second gain mode to the first gain mode with hysteresis with respect to the signal amplitude at the input of the amplifier.

7. A mobile radio receiver according to claim 2, comprising an analogue/digital converter which is arranged in the signal path on the output side of the amplifier and is used for the comparison by the second comparator and, furthermore, for at least one further function within the mobile radio receiver.

8. A mobile radio receiver according to claim 7,
comprising
a means for provision of digital, in particular logarithmic, RSSI information, which means comprises the analogue/digital converter.

9. A mobile radio receiver according to claim 8,
wherein
the second comparator is designed such that it compares the RSSI information, a variable derived from it or an intermediate variable in the formation of the RSSI information with the digital second comparison value.

10. A mobile radio receiver according to claim 7,
wherein
the analogue/digital converter operates on the basis of an iterative method, in particular on the basis of the method of successive approximation, and has
a further comparator and
a digital/analogue converter which drives the reference input of the further comparator,
in which case the digital/analogue converter can be supplied with
the digital second comparison value
in addition to a digital comparison variable for analogue/digital conversion of the input signal in the analogue/digital converter.

11. A mobile radio receiver according to claim 10,
wherein
the second comparator is designed such that the comparison is carried out by
reading the digital second comparison value to the digital/analogue converter, and
reading the output signal from the further comparator.

12. A mobile radio receiver according to claim 1,
wherein the mobile radio receiver is a Bluetooth mobile radio receiver.

13. A method for setting the gain of a variable gain amplifier in a mobile radio receiver, comprising the step of setting the gain selectively or cumulatively as a function of
a first comparison of a first signal, which is characteristic of the amplitude of a received signal, with at least one analogue first comparison value, or
a second comparison of a second signal, which is characteristic of the amplitude of a received signal, with at least one digital second comparison value.

14. A method according to claim 13,
wherein
the first signal is characteristic of the signal amplitude at the amplifier output, and
the second signal is characteristic of the signal amplitude at the amplifier output.

15. A method according to claim 14,
wherein
for first values of the signal amplitude of the amplifier output signal, the gain is set as a function of the second comparison, and
for second values of the signal amplitude of the amplifier output signal which are greater than the first values, the gain is set as a function of the first comparison.

16. A method according to claim 14,
wherein
the amplifier can be operated, at least in a first gain mode, with a first magnitude V1 of the gain, and can be operated in a second gain mode with a second magnitude V2 of the gain, where V1<V2, and
the gain of the amplifier is set such that
switching takes place from the first gain mode to the second gain mode as a function of the second comparison, and
switching takes place from the second gain mode to the first gain mode as a function of the first comparison.

17. A method according to claim 16,
wherein the gain is set such that
switching takes place from the first gain mode to the second gain mode when the second comparison shows that the second signal, which is characteristic of the signal amplitude at the amplifier output, has fallen below the digital second comparison value, and
switching takes place from the second gain mode to the first gain mode when the first comparison shows that the first signal, which is characteristic of the signal amplitude at the amplifier output, has exceeded the analogue first comparison value.

18. A method according to claim 16,
wherein
the analogue first comparison value and the digital second comparison value are chosen such that switching takes place from the first gain mode to the second gain mode, and switching takes place from the second gain mode to the first gain mode with hysteresis with respect to the signal amplitude at the input of the amplifier.

19. A method according to claim 14,
wherein
in the second comparison, digital, in particular logarithmic, RSSI information which is available in the mobile radio receiver, a variable derived from this information or an intermediate variable in the formation of the RSSI information is compared with the digital second comparison value.

20. A method according to claim 14,
wherein
digital, in particular logarithmic, RSSI information is obtained by iterative analogue/digital conversion, in particular based on the method of successive approximation, using
a comparator and
a digital/analogue converter which drives the reference input of the comparator, wherein steps of
a) reading the digital second comparison value to the digital/analogue converter, and
b) reading the output signal from the comparator
are carried out during the iterative analogue/digital conversion for the second comparison.

21. A method according to claim 19,
wherein
digital, in particular logarithmic, RSSI information is obtained by iterative analogue/digital conversion, in particular based on the method of successive approximation, using
a comparator and
a digital/analogue converter which drives the reference input of the comparator, wherein steps of
a) reading the digital second comparison value to the digital/analogue converter, and
b) reading the output signal from the comparator
are carried out during the iterative analogue/digital conversion for the second comparison, and wherein during the second comparison
the RSSI information, a variable derived from it or an intermediate variable in the formation of the RSSI information is compared with the digital second comparison value at a time after the determination of the digital logarithmic RSSI information, and
the steps a) and b) are furthermore carried out once or more during the iterative analogue/digital conversion.

22. A method according to claim 16,
wherein
the amplifier is in the second gain mode before the gain is set.

23. A method according to claim 13,
wherein
the method relates to gain setting carried out in a Bluetooth mobile radio receiver.
